(19) United States
(12) Patent Application Publication
(10) Pub. No.: US 2008/0017110 A1
(43) Pub. Date: Jan. 24, 2008

(54) Rotation evaporator for thin film deposition and thin film deposition apparatus using the same

(75) Inventor: Kyong-Ho Kim, Gyeonggi-do (KR)

Correspondence Address: MYERS BIGEL SIBLEY & SAJOVEC, PO BOX 37428, RALEIGH, NC, 27627, US

(73) Assignee: Semes Co., Ltd.

(21) Appl. No.: 11/825,684

(22) Filed: Jul. 9, 2007

(30) Foreign Application Priority Data
Jul. 18, 2006 (KR) 10-2006-0066962

(51) Int. Cl. C23C 16/04

(52) U.S. Cl. 118/721; 118/726

(57) ABSTRACT

A rotation evaporator for thin film deposition and a thin film deposition apparatus using the same are provided. The rotation evaporator includes a melting pot that has an opened top surface and in which a deposition material is filled, a heating unit that heats the melting pot, and a rotation unit that rotates the evaporator using predetermined electric power to be supplied from the outside. The thin film deposition apparatus that uses a rotation evaporator includes a substrate that is to be subject to deposition, a mask that is coupled to the substrate so as to cover a portion to be not deposited of the substrate and to deposit a necessary portion of the substrate, a substrate chucking system that supports the substrate and the mask, and an evaporator that rotates using a rotation unit. The rotation unit includes a melting pot that has an opened top surface and in which a deposition material is filled, and a heating unit that heats the melting pot.

### CROSS REFERENCE TO RELATED APPLICATION

This application claims priority from Korean Patent Application No. 10-2006-0066962 filed on Jul. 18, 2006 in the Korean Intellectual Property Office, the disclosure of which is incorporated herein by reference in its entirety.

### BACKGROUND OF THE INVENTION

1. Field of the Invention

The present invention relates to an apparatus for rotating an evaporator that deposits an organic material, and more particularly, to an apparatus for thin film deposition that can efficiently perform uniform deposition on a substrate by rotating an evaporator instead of a substrate, compared with a case of rotating a substrate.

2. Description of the Related Art

As the Internet is becoming widespread, technologies related to data processing, applications, data transfer, and the like are being rapidly developed. Accordingly, as digital data transfer rates are being rapidly increased, there is a demand for the development of a display device that can display moving images and the like at a corresponding response speed. Recently, an organic EL having a high response speed has been attracting attention. The organic EL has many advantages, such as a high response speed, lower power consumption than the existing liquid crystal displays, and excellent luminance, and is light-weight and thin, and thus it is becoming the next generation display.

The organic EL has an ITO anode film, an organic thin film, and a metal cathode film that are coated on a glass substrate. Then, a voltage is applied between the anode and the cathode such that an appropriate difference in energy is formed in the organic thin film between the anode and the cathode, and then the organic EL emits light. That is, light is generated by energy emitted when injected electrons and holes are recombined. At this time, the wavelength of emitted light can be adjusted according to the amount of a dopant of an organic material, thereby implementing natural colors (RGB). As for the structure, an ITO (Indium Tin Oxide) film having low resistance and good transmittance, an organic thin film that has a multilayer of HIL, HTL, EML, ETL, and EIL to increase light-emission efficiency, and a metal film (LiF—Al) are laminated. The organic material to be used includes Alq3, TPD, PBD, m-MTDATA, TCTA, or the like, and the dopant includes cumarine 6, BczVBi, or the like.

The characteristics of the organic EL are primarily defined by an organic thin film layer, and a multilayer organic thin film is formed by a vacuum deposition method that uses deposition under a high vacuum atmosphere to form pixel patterns of the organic material through a shadow mask. In a vacuum chamber where the multilayer organic thin film is deposited, a deposition material of the organic material, an evaporator, an alignment device of the glass substrate and the mask, a vision system notifying whether or not the mask and the substrate are accurately aligned with each other, a thickness monitor, and the like are provided.

FIG. 1 is a conceptual view of a known deposition apparatus for uniform deposition.

According to the related art, for uniform deposition, deposition is performed by rotating a mask 10, a substrate 20, a substrate chucking system 40, and the like.

However, the larger the substrate 20, the substrate chucking system 40 that holds the substrate and the mask at an upper end of the chamber needs to be larger. As a result, there is a difficulty in rotating the substrate. Further, since the mask alignment device or the vision system is provided at the upper end of the chamber, it may also obstruct the rotation of the substrate 20 and the like. In addition, there are various limitations, for example, the mask 10 and the substrate 20 that face each other must rotate with a very limited space.

### SUMMARY OF THE INVENTION

The invention has been finalized in order to solve the above-described problems, and an object of the invention is to easily design a deposition apparatus for uniform deposition by rotating an evaporator instead of a substrate and the like, and to reduce operation cost of the deposition apparatus.

Objects of the present invention are not limited to those mentioned above, and other objects of the present invention will be apparently understood by those skilled in the art through the following description.

A rotation evaporator for thin film deposition and a thin film deposition apparatus using the same are provided.

According to an aspect of the invention, there is provided a rotation evaporator including a melting pot that has an opened top surface and in which a deposition material is filled, a heating unit that heats the melting pot, and a rotation unit that rotates the evaporator using predetermined electric power to be supplied from the outside.

According to another aspect of the invention, there is provided a thin film deposition apparatus that uses a rotation evaporator, the apparatus including a substrate to be subjected to deposition, a mask coupled to the substrate so as to cover a portion to be not deposited of the substrate and to deposit a necessary portion of the substrate, a substrate chucking system supporting the substrate and the mask, and an evaporator that rotates using a rotation unit. The rotation unit includes a melting pot that has an opened top surface and in which a deposition material is filled, and a heating unit that heats the melting pot.

### BRIEF DESCRIPTION OF THE DRAWINGS

The above and other features and advantages of the present invention will become more apparent by describing in detail preferred embodiments thereof with reference to the attached drawings, in which:

FIG. 1 is a conceptual view of a known deposition apparatus for uniform deposition;

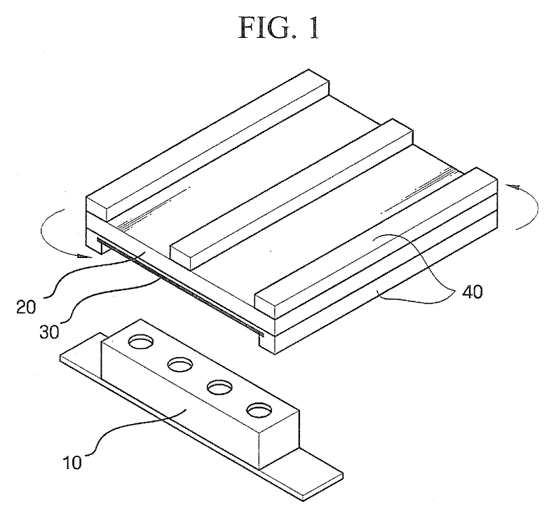

FIG. 2 is a diagram showing a thin film deposition apparatus that uses a rotation evaporator according to an embodiment of the invention;

FIG. 3 is a diagram showing a thin film deposition apparatus that uses a rotation evaporator rotating an evaporator using a motor according to an embodiment of the invention;

FIG. 4 is a diagram showing a thin film deposition apparatus that uses a rotation evaporator rotating an evaporator using a belt according to an embodiment of the invention; and

FIG. 5 is a diagram showing a thin film deposition apparatus that uses a rotation evaporator rotating an evaporator using a gear according to an embodiment of the invention.

### DESCRIPTION OF THE PREFERRED EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. Like reference numerals refer to like elements throughout the specification.

Hereinafter, the invention will be described by way of embodiments of the invention with reference to the drawings that illustrates a linear evaporator for thin film deposition.

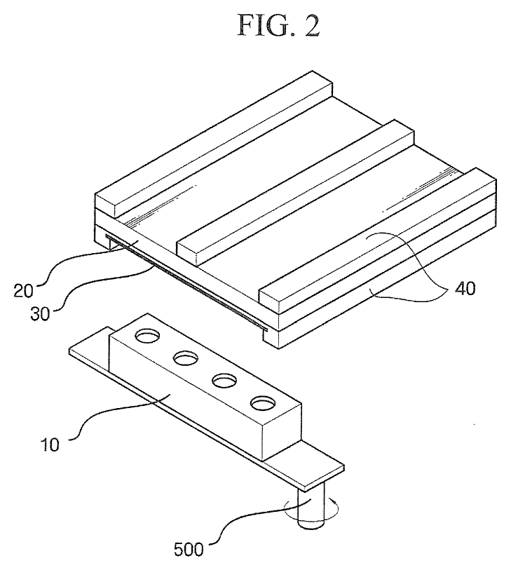

FIG. 2 is a diagram showing a thin film deposition apparatus that uses a rotation evaporator according to an embodiment of the invention.

A thin film deposition apparatus that uses a rotation evaporator according to an embodiment of the invention includes an evaporator 10, a substrate 20, a mask 30, a substrate chucking system 40, and a shaft 500 that is coupled to the evaporator 10.

The evaporator 10 includes a melting pot that has an opened top surface and in which a deposition material is filled, and a heating unit that heats the melting pot. On the substrate 20, a deposition material evaporated by the evaporator is deposited, and a glass substrate or the like is used. The mask 30 performs patterning by covering a portion to be not deposited of the substrate, to thereby a pixel at a desired portion of the substrate. During a deposition process, the substrate 20 and the mask 30 are coupled to each other. The substrate chucking system 40 supports the substrate 20 and the mask 30 that are coupled to each other, and thus they are located at an upper portion of the vacuum chamber. The shaft 500 is coupled to the evaporator 10 so as to rotate the evaporator 10, and energy for rotating the evaporator is transferred through the shaft 500.

For uniform deposition, in the related art, the substrate 20, the mask 30, and the substrate chucking system 40 that supports the substrate 20 and the mask 30 rotate. Alternatively, according to an embodiment of the invention, the evaporator 10 that is located below the substrate 20 rotates. The shaft 500 is provided at a lower surface of the evaporator 10 in order to rotate the evaporator 10.

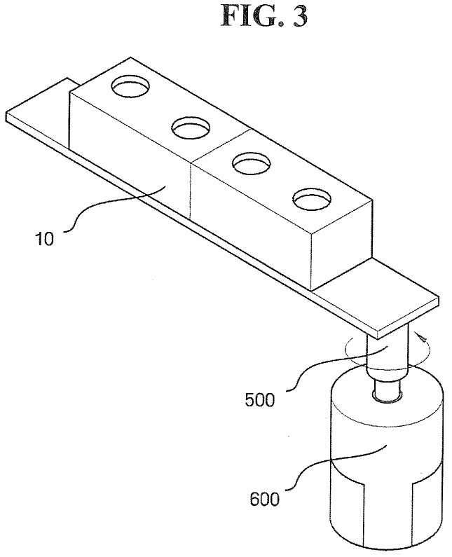

FIG. 3 is a diagram showing a thin film deposition apparatus that uses a rotation evaporator rotating the evaporator 10 using a motor according to an embodiment of the invention.

In order to rotate the evaporator 10, a motor 600 may be coupled to the shaft 500 of the thin film deposition apparatus that uses the rotation evaporator and that includes the evaporator 10, the substrate 20, the mask 30, the substrate chucking system 40, and the shaft 500 coupled to the evaporator 10, according to the embodiment of the invention.

The motor 600 may be provided inside the vacuum chamber or outside the vacuum chamber.

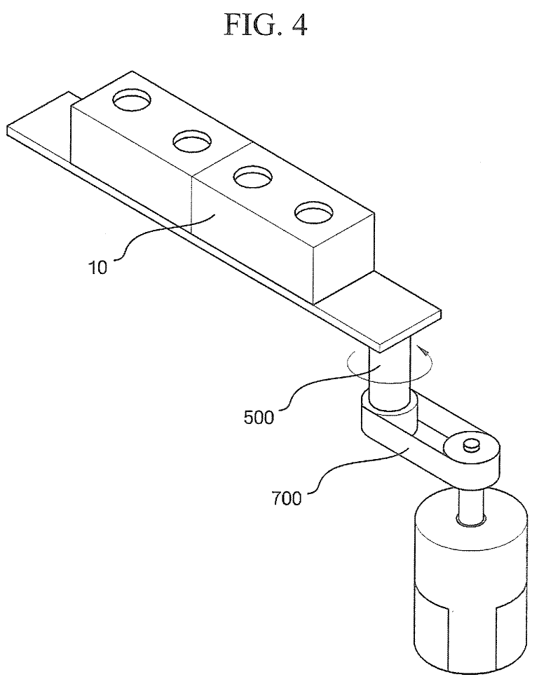

FIG. 4 is a diagram showing a thin film deposition apparatus that uses the rotation evaporator rotating the evaporator 10 using a belt according to an embodiment of the invention.

In order to rotate the evaporator 10, a belt may be coupled to the shaft of the thin film deposition apparatus that uses the rotation evaporator and that includes the evaporator 10, the substrate 20, the mask 30, the substrate chucking system 40, and the shaft 500 coupled to the evaporator 10 according to an embodiment of the invention.

At this time, when energy is supplied to the belt 700 through an energy supply apparatus, the evaporator 10 rotates using the belt 700. The belt 700 and the apparatus for supplying energy to the belt 700 may be provided inside or outside the vacuum chamber according to individual situations.

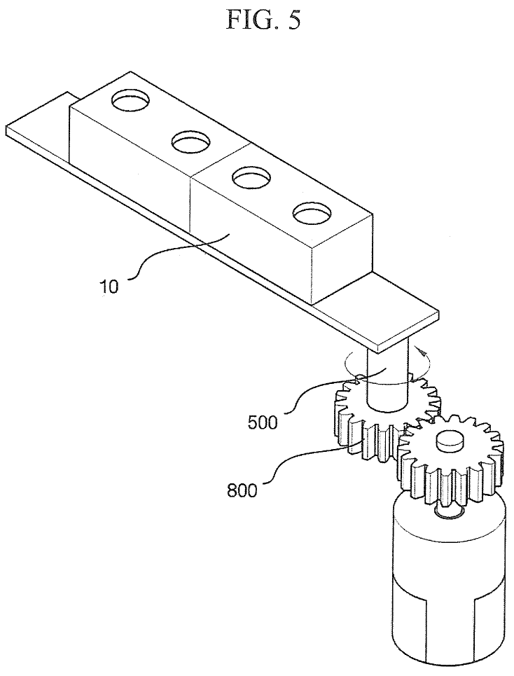

FIG. 5 is a diagram showing a thin film deposition apparatus that uses the rotation evaporator rotating the evaporator 10 using a gear according to an embodiment of the invention.

In order to rotate the evaporator 10, a gear 800 may be coupled to the shaft 500 of the thin film deposition apparatus that uses the rotation evaporator and that includes the evaporator 10, the substrate 20, the mask 30, the substrate chucking system 40, and the shaft 500 coupled to the evaporator 10, according to an embodiment of the invention.

At this time, when energy is supplied to the gear 800 through an energy supply apparatus, the evaporator 10 rotates using the gear 800. The gear 800 and an apparatus for supplying energy to the gear 800 may be provided inside or outside the vacuum chamber according to individual situations.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects. The scope of the present invention is defined by the appended claims rather than by the description preceding them, and all changes and modifications that fall within meets and bounds of the claims, or equivalents of such meets and bounds are therefore intended to be embraced by the claims.

As described above, according to the invention, a misalignment between the substrate and the mask that may occur when the substrate and the mask rotate together with the substrate chucking system can be prevented, and design and cost loads for rotating the substrate chucking system can be reduced.

What is claimed is:

1. A rotation evaporator for thin film deposition, the evaporator comprising:
a melting pot that has an opened top surface, into which a deposition material is filled;
a heating unit that heats the melting pot; and
a rotation unit that rotates the evaporator using predetermined electric power to be supplied from the outside.

2. The rotation evaporator of claim 1, wherein the rotation unit has a shaft that is provided at a lower end of the evaporator and a motor that is coupled to the shaft.

3. The rotation evaporator of claim 1, wherein the rotation unit rotates the evaporator by connecting a shaft provided at a lower end of the evaporator and a belt.

4. The rotation evaporator of claim 1, wherein the rotation unit rotates the evaporator using a shaft provided at a lower end of the evaporator and a saw-toothed screw.

5. A thin film deposition apparatus that uses a rotation evaporator, the apparatus comprising:
a substrate that is to be subject to deposition;
a mask that is coupled to the substrate so as to cover a portion to be not deposited of the substrate and to deposit a necessary portion of the substrate;
a substrate chucking system that supports the substrate and the mask; and
an evaporator that rotates using a rotation unit,
wherein the evaporator comprises a melting pot that has an opened top surface and in which a deposition material is filled, and a heating unit that heats the melting pot.
